(19) United States
(12) Patent Application Publication
(10) Pub. No.: US 2026/0122764 A1
(43) Pub. Date: Apr. 30, 2026

(54) INTEGRATED HEAT SINK FOR COMPUTING STRUCTURE

(71) Applicant: Quanta Computer Inc., Taoyuan City (TW)

(72) Inventor: Ching-Jen CHEN, Taoyuan City (TW)

(21) Appl. No.: 18/932,582

(22) Filed: Oct. 30, 2024

(51) Int. Cl. H05K 1/02

(52) U.S. Cl. CPC H05K 1/0209; H05K 1/0218; H05K 2201/064; H05K 2201/10416

(57) ABSTRACT

A computing device includes a printed circuit board (PCB) having a ground plane and a power plane. The ground plane has a length L1 that extends between a first ground edge and a second ground edge. The power plane has a length L2 that extends between a first power edge and a second power edge. The ground plane is parallel to and separated from the power plane by a distance H. The computing device further includes a heat sink integrated with the PCB. The heat sink is parallel to and coupled to the power plane. The heat sink has a length L3 that extends between a first sink edge and a second sink edge. The length L3 of the heat sink is greater than at least one of the length L1 of the ground plane or the length L2 of the power plane.

### FIELD OF THE INVENTION

The present invention relates generally to computing systems, and more specifically, to a heat sink for reducing electromagnetic interference (EMI) from edges of a printed circuit board (PCB) having multiple layers of material.

### BACKGROUND OF THE INVENTION

Electromagnetic radiation can be emitted from the edges of a PCB having multiple layers of material. When an electromagnetic wave reaches the edge of the PCB, adjacent layers of the PCB can act like a slot antenna, potentially emitting noise that could cause EMI to nearby devices. The EMI emitted from the edges of the PCB can be mitigated by adding a series of structures around a perimeter of the PCB, forming a “picket fence” structure. The EMI can also be mitigated by shrinking the size of a layer of the PCB relative to an adjacent layer. However, these mitigation solutions can restrict the available area for placing components and routing traces. The present disclosure provides a solution for this and other problems.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing device includes a printed circuit board (PCB) having a ground plane and a power plane. The ground plane has a length L1 that extends between a first ground edge and a second ground edge. The power plane has a length L2 that extends between a first power edge and a second power edge. The ground plane is parallel to and separated from the power plane by a distance H. The computing device further includes a heat sink integrated with the PCB. The heat sink is parallel to and coupled to the power plane. The heat sink has a length L3 that extends between a first sink edge and a second sink edge. The length L3 of the heat sink is greater than at least one of the length L1 of the ground plane or the length L2 of the power plane.

According to certain aspects of the present disclosure, in the computing device described above, the first sink edge extends a distance that is at least about 10H past at least one of the first ground edge or the first power edge.

According to certain aspects of the present disclosure, in the computing device described above, the first sink edge extends a distance that is at least about 20H past at least one of the first ground edge or the first power edge.

According to certain aspects of the present disclosure, in the computing device described above, the first sink edge extends a distance that is at least about 100H past at least one of the first ground edge or the first power edge.

According to certain aspects of the present disclosure, in the computing device described above, heat-generating components are mounted on the PCB. The heat sink is coupled to the power plane via thermal contact with the heat-generating components.

According to certain aspects of the present disclosure, the heat sink includes a plurality of fins to dissipate the heat generated by the heat-generating components.

According to certain aspects of the present disclosure, in the computing device described above, the PCB is contained in a chassis and the heat sink forms a wall of the chassis.

According to certain aspects of the present disclosure, in the computing device described above, the plurality of fins extends from the wall to an exterior of the chassis.

According to certain aspects of the present disclosure, in the computing device described above, the heat sink is a cold plate that is cooled via an external coolant.

According to certain aspects of the present disclosure, in the computing device described above, the heat sink is made from aluminum, zinc, or magnesium.

According to certain aspects of the present disclosure, in the computing device described above, the PCB has a plurality of ground planes and routing layers. Spaces between the ground planes and routing layers are filled by laminate materials.

According to other aspects of the present disclosure, a computing system includes a chassis and a PCB housed within the chassis. The PCB has a ground plane and a power plane. The ground plane has a length L1 that extends between a first ground edge and a second ground edge. The power plane has a length L2 that extends between a first power edge and a second power edge. The ground plane is separated from the power plane by a distance H. The computing device further includes a heat sink formed as a wall of the chassis. The heat sink is integrated with the PCB. The heat sink is coupled to the power plane. The heat sink has a length L3 that extends between a first sink edge and a second sink edge. The length L3 of the heat sink is greater than at least one of the length L1 of the ground plane or the length L2 of the power plane.

According to certain aspects of the present disclosure, in the computing system described above, the first sink edge extends a distance that is at least about 10H past at least one of the first ground edge or the first power edge.

According to certain aspects of the present disclosure, in the computing system described above, the first sink edge extends a distance that is at least about 20H past at least one of the first ground edge or the first power edge.

According to certain aspects of the present disclosure, in the computing system described above, the first sink edge extends a distance that is at least about 100H past at least one of the first ground edge or the first power edge.

According to certain aspects of the present disclosure, in the computing system described above, heat-generating components are mounted on the PCB. The heat sink is coupled to the power plane via thermal contact with the heat-generating components.

According to certain aspects of the present disclosure, in the computing system described above, the heat sink includes a plurality of fins to dissipate the heat generated by the heat-generating components. The plurality of fins extends from the wall to an exterior of the chassis.

According to certain aspects of the present disclosure, in the computing system described above, the heat sink is a cold plate that is cooled via an external coolant.

According to certain aspects of the present disclosure, in the computing system described above, the heat sink is made from aluminum, zinc, or magnesium.

According to certain aspects of the present disclosure, in the computing system described above, the PCB has a plurality of ground planes and routing layers. Spaces between the ground planes and routing layers are filled by laminate materials.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments and are therefore not to be considered as limitations on the scope of the various embodiments or claims.

FIG. 1 is a schematic elevational view of an exemplary PCB showing a power plane and a ground plane separated by a distance H, according to certain aspects of the present disclosure.

FIG. 2 is a tabular description of layers within an exemplary 12 layer PCB, according to certain aspects of the present disclosure.

FIG. 3 is a schematic external perspective view of a computing device, according to certain aspects of the present disclosure.

FIG. 4 is a cross-sectional view of the computing device of FIG. 3 taken generally along the lines 4-4 of FIG. 3, according to certain aspects of the present disclosure.

### DETAILED DESCRIPTION

The current invention is computing device having a heat sink integrated with a PCB that includes a ground plane and a power plane separated by a distance H. The heat sink has a length that is greater than at least one of the length of the ground plane and the power plane by a predetermined multiple of H. The greater length of the heat sink results in suppression of electromagnetic radiation being emitted beyond the edges of the ground plane and the power plane. The suppression of the electromagnetic radiation reduces EMI from the edges of the PCB.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

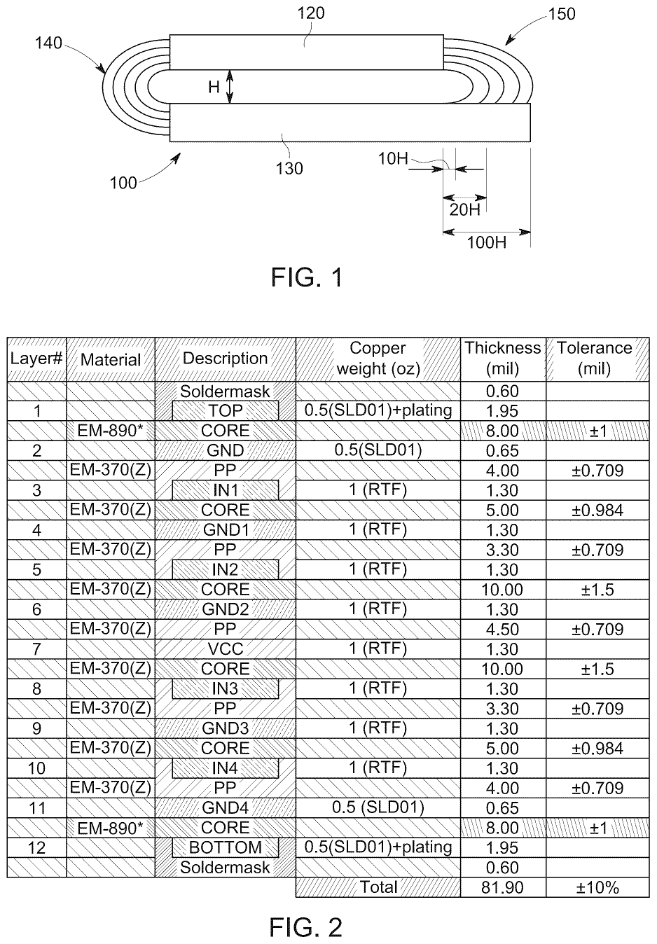

Referring to FIG. 1, two layers of an exemplary PCB 100 are shown schematically in cross-section. A power plane 120 is separated by a ground plane 130 by a separation distance H. For purposes of clarity in description, the separation distance H in FIG. 1 (and in FIG. 4) is shown to be larger than actual size. As shown at 140, electromagnetic radiation is emitted beyond the aligned left edges of the power plane 120 and the ground plane 130. This unsuppressed radiation 140 can cause EMI to nearby devices. However, it is known that an extension of the ground plane 130 beyond an edge of the power plane 120 results in a suppression of electromagnetic radiation, such as the electromagnetic radiation 150 emitted beyond the ground plane 130. For example, extending the ground plane 130 by about 100H results in the suppressed radiation 150. In this example, the suppressed radiation 150 is reduced by about 98% compared to the unsuppressed radiation 140.

Referring to FIG. 2, an exemplary stack-up of layers of a 12-layer PCB is presented in tabular format for reference and context. In this example, top and bottom surfaces of the PCB are covered by a solder mask, which provides a protective coating for the PCB. Layer 7 is labeled as VCC, which indicates layer 7 to be the main power layer. Layers 1, 3, 5, 8, 10, and 12 are conductive routing layers. Layers 2, 4, 6, 9 and 11 are ground layers. Between the conductive routing layers and the ground layers are additional layers of PCB laminate material, labeled as EM-370 (Z) and EM-890*. It is of note that the top two adjacent parallel planes of the exemplary 12-layer PCB are separated by a laminate layer that is 8 mils thick. In this example H is about 8 mils, which results in 100H being about 800 mils.

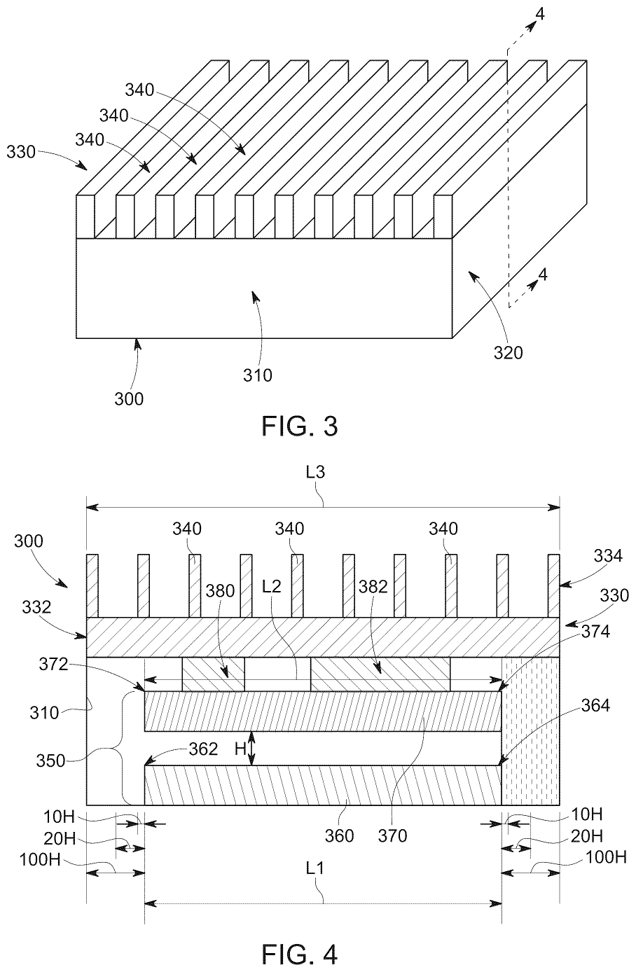

Referring to FIG. 3, a computing system 300 is disclosed as an exemplary device that is used in telecommunications systems. The computing system 300, for example, 5G equipment, is often packaged for protection from environmental conditions and unauthorized access. For example, the computing system 300 (or similar computing devices) is often enclosed and designed to fit in a limited space, such as a cabinet or small closet. As a result, the computing system 300 includes a one-piece overhead heat sink mechanism built into a chassis for cooling.

More specifically, the computing system 300 has a chassis 310 that includes a top wall 320. The computing system 300 further includes a heat sink 330 attached to the top wall 320. The heat sink 330 has a plurality of fins 340 that dissipate heat from heat-generating components disposed within the chassis 310 (e.g., processors). The plurality of fins 340 extends from the top wall 320 to an exterior of the chassis 310.

Referring to FIG. 4, the computing system 300 further includes a PCB 350 that includes a ground plane 360 and a power plane 370. The PCB 350 is similar to the PCB 100 shown in FIG. 1, but is not limited to having two layers as shown in FIG. 1. The PCB 350 can have as many layers as required by a particular application, including for example without limitation, the structure of the 12-layer PCB illustrated in FIG. 2. The ground plane 360 has a length L1 that extends between a first ground edge 362 and a second ground edge 364. The power plane 370 has a length L2 that extends between a first power edge 372 and a second power edge 374. The ground plane 360 is parallel to and separated from the power plane 370 by a distance H.

The computing system 300 includes the heat sink 330 integrated with the PCB 350. The heat sink 330 is parallel to and coupled to the power plane 370. The heat sink 330 has a length L3 that extends between a first sink edge 332 and a second sink edge 334. The length L3 of the heat sink 330 is greater than at least one of the length L1 of the ground plane 360 or the length L2 of the power plane 370.

In one example, the first sink edge 332 extends a distance that is at least about 10H past at least one of the first ground edge 362 or the first power edge 372. In other examples, the first sink edge 332 extends a distance that is at least about 20H or at least 100H past at least one of the first ground edge 362 or the first power edge 372. In still further examples, the first sink edge 332 extends a distance that is at least about a predetermined multiple of H past at least one of the first ground edge 362 or the first power edge 372, where the predetermined multiple of H satisfies PCB edge EMI suppression requirements.

Still referring to FIG. 4, the PCB 350 has a plurality of heat-generating components 380, 382. In this example, the heat sink 330 is coupled to the power plane 370 by thermal contact with the heat-generating components 380, 382. For example, and without limitation, each of the heat-generating components 380, 382 is a central processing unit (CPU), a system on chip (SoC), a memory module, a PCI Express card, and/or a chipset.

According to one specific example, the heat sink 330 is a cold plate that is cooled via an external coolant. According to other examples, the heat sink 330 is made from a metal material, such as aluminum, zinc, or magnesium.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing device comprising:
a printed circuit board (PCB) having a ground plane and a power plane, the ground plane having a length L1 that extends between a first ground edge and a second ground edge, the power plane having a length L2 that extends between a first power edge and a second power edge, the ground plane being parallel to and separated from the power plane by a distance H; and
a heat sink integrated with the PCB, the heat sink being parallel to and coupled to the power plane, the heat sink having a length L3 that extends between a first sink edge and a second sink edge, the length L3 of the heat sink being greater than at least one of the length L1 of the ground plane or the length L2 of the power plane.

2. The computing device of claim 1, wherein the first sink edge extends a distance that is at least about 10H past at least one of the first ground edge or the first power edge.

3. The computing device of claim 1, wherein the first sink edge extends a distance that is at least about 20H past at least one of the first ground edge or the first power edge.

4. The computing device of claim 1, wherein the first sink edge extends a distance that is at least about 100H past at least one of the first ground edge or the first power edge.

5. The computing device of claim 1, further comprising heat-generating components mounted on the PCB, the heat sink being coupled to the power plane via thermal contact with the heat-generating components.

6. The computing device of claim 1, wherein the heat sink includes a plurality of fins to dissipate the heat generated by the heat-generating components.

7. The computing device of claim 6, further comprising a chassis in which the PCB is contained, the heat sink forming a wall of the chassis.

8. The computing device of claim 7, wherein the plurality of fins extends from the wall to an exterior of the chassis.

9. The computing device of claim 8, wherein the heat sink is a cold plate that is cooled via an external coolant.

10. The computing device of claim 1, wherein the heat sink is made from aluminum, zinc, or magnesium.

11. The computing device of claim 1, wherein the PCB has a plurality of ground planes and routing layers, and a laminate material is disposed in each space between the plurality of ground planes and routing layers.

12. A computing system comprising:
a chassis;
a printed circuit board (PCB) housed within the chassis, the PCB having a ground plane and a power plane, the ground plane having a length L1 that extends between a first ground edge and a second ground edge, the power plane having a length L2 that extends between a first power edge and a second power edge, the ground plane being separated from the power plane by a distance H; and
a heat sink formed as a wall of the chassis, the heat sink integrated with the PCB, the heat sink being coupled to the power plane, the heat sink having a length L3 that extends between a first sink edge and a second sink edge, the length L3 of the heat sink being greater than at least one of the length L1 of the ground plane or the length L2 of the power plane.

13. The computing system of claim 12, wherein the first sink edge extends a distance that is at least about 10H past at least one of the first ground edge or the first power edge.

14. The computing system of claim 12, wherein the first sink edge extends a distance that is at least about 20H past at least one of the first ground edge or the first power edge.

15. The computing system of claim 12, wherein the first sink edge extends a distance that is at least about 100H past at least one of the first ground edge or the first power edge.

16. The computing system of claim 12, further comprising heat-generating components mounted on the PCB, the heat sink being coupled to the power plane via thermal contact with the heat-generating components.

17. The computing system of claim 16, wherein the heat sink includes a plurality of fins to dissipate the heat generated by the heat-generating components, the plurality of fins extending from the wall to an exterior of the chassis.

18. The computing system of claim 17, wherein the heat sink is a cold plate that is cooled via an external coolant.

19. The computing system of claim 12, wherein the heat sink is made from aluminum, zinc, or magnesium.

20. The computing system of claim 12, wherein the PCB has a plurality of ground planes and routing layers, and a laminate material is disposed in each space between the plurality of ground planes and routing layers.
